(19) United States
(12) Patent Application Publication
(10) Pub. No.: US 2017/0299734 A1
(43) Pub. Date: Oct. 19, 2017

(54) X-RAY DETECTOR AND DRIVING METHOD THEREFOR

(71) Applicants: Rayence Co., Ltd., Gyeonggi-do (KR); VATECH EWOO Holdings Co., Ltd., Gyeonggi-do (KR)

(72) Inventors: Dong-Jin LEE, Gyeonggi-do (KR); Tae-Woo KIM, Gyeonggi-do (KR); Yu-Sung JEON, Gyeonggi-do (KR)

(73) Assignees: Rayence Co., Ltd., Gyeonggi-do (KR); VATECH EWOO Holdings Co., Ltd., Gyeonggi-do (KR)

(21) Appl. No.: 15/515,639

(22) PCT Filed: Sep. 30, 2015
(86) PCT No.: PCT/KR2015/010273

§ 371 Date: Mar. 30, 2017

(30) Foreign Application Priority Data
Sep. 30, 2014 (KR) 10-2014-0131406

(51) Int. Cl. G01T 1/24

(52) U.S. Cl. CPC G01T 1/241

(57) ABSTRACT

Disclosed is an x-ray detector includes a first electrode formed on a substrate, a photoconductive layer formed on the first electrode, a second electrode formed on the photoconductive layer and configured to be in a voltage applied state with a bias voltage or a floating state, and a power supply circuit configured to control an output of the bias voltage to be on/off.

### TECHNICAL FIELD

The present invention relates to an X-ray detector. More particularly, the present invention relates to an X-ray detector capable of reducing power consumption by controlling application of a bias voltage, and a method of driving the X-ray detector.

### BACKGROUND ART

Conventionally, in X-ray radiography for medical or industrial purposes, a combination of a film and a screen is used. This method is not cost-effective and is time-consuming due to problems associated with development and storage of a photographic film.

Because of this problem, digital detectors are now widely used. Digital detectors are classified into an indirection conversion type and a direct conversion type.

An indirect conversion digital detector first converts X-rays into visible light using a scintillator and then converts the visible light into an electrical signal. Meanwhile, a direct conversion digital detector directly converts X-rays into an electrical signal using a photoconductive layer. Direct conversion digital detectors are advantageous in that they do not require a scintillator and are free of light spread. Thus direct conversion digital detectors are suitable for use in high resolution imaging systems.

A photoconductive layer used in a direct conversion digital detector is formed by depositing polycrystalline silicon such as CdTE on the surface of a CMOS substrate through vacuum thermal evaporation.

An upper electrode and a lower electrode are respectively provided on and under the photoconductive layer. Electric charges generated in the photoconductive layer by X-ray irradiation are collected by the lower electrode. For this operation, a driving voltage is applied to the lower electrode and a bias voltage is applied to the upper electrode.

In conventional direct conversion digital detectors, a constant high-level voltage as the bias voltage is continuously applied to the upper electrode. Due to the continued application of the high-level voltage to the upper electrode, conventional detectors consume much power.

### DISCLOSURE

### Technical Problem

Accordingly, the present invention has been made keeping in mind the above problems occurring in the conventional art, and an object of the present invention is to propose power consumption reduction measures for an X-ray detector.

### Technical Solution

In order to accomplish the above object, the present invention provides an X-ray detector including: a first electrode formed on a substrate; a photoconductive layer formed on the first electrode layer; a second electrode formed on the photoconductive layer and configured to be in a voltage applied state with a bias voltage or a floating state; and a power supply circuit configured to control an output of a bias voltage to be on/off.

The power supply circuit may select any level bias voltage ranging from a first-level bias voltage to an N-th-level bias voltage, and may be configured to control an output of the selected bias voltage to be on/off, wherein the N may be 2 or greater.

The power supply circuit may include a voltage generator that generates from the first-level bias voltage to the N-th-level bias voltage and a selector that selects any level bias voltage ranging from the first-level bias voltage to the N-th-level bias voltage.

The power supply circuit may control an output of the bias voltage to be on/off, such that the second electrode is in a voltage applied state or in a floating state.

The photoconductive layer is made from at least any one material selected from a group consisting of CdTe, CdZnTe, PbO, PbI₂, HgI₂, GaAs, Se, TlBr, and BiI₃.

The X-rays are incident onto the second electrode or the back surface of the substrate.

The second electrode may be made from any one selected from gold (Au), platinum (Pt), and alloys of these.

In order to accomplish the object of the present invention, according to another aspect, there is provided a method of driving an X-ray detector, the method including: preparing an X-ray detector including a first electrode formed on a substrate, a photoconductive layer formed on the first electrode, and a second electrode formed on the photoconductive layer; irradiating X-rays on a X-ray detector while the upper electrode to be in a voltage applied state with a bias voltage or in a floating state, by controlling an output of the bias voltage to be on/off.

The power supply circuit may select any level bias voltage ranging from a first-level bias voltage to an N-th-level bias voltage, and may be configured to control an output of the selected bias voltage to be on/off, wherein the N is 2 or greater.

### Advantageous Effects

According to the present invention, the control of the application of the bias voltage is performed in the following manner: the voltage level of the bias voltage applied to the upper electrode is adjusted in accordance with required image quality; or electrical connection between the upper electrode and the power supply circuit is cut off so that the upper electrode becomes floating. Accordingly, as compared with conventional arts in which a high-level voltage is continuously applied to the upper electrode regardless of required image quality, power consumption is considerably reduced.

Furthermore, the present invention can be applied to back side irradiation systems as well as front side irradiation systems.

### DESCRIPTION OF DRAWINGS

FIG. 1 is a schematic diagram illustrating an X-ray detector according to one embodiment of the present invention;

FIG. 2 is a cross-sectional view illustrating the pixel construction of the X-ray detector according to one embodiment of the present invention; and

FIG. 3 is a schematic diagram illustrating a power supply circuit according to one embodiment of the present invention.

### BEST MODE

### Mode for Invention

Hereinafter, embodiments of the present invention will be described in detail with reference to the accompanying drawings.

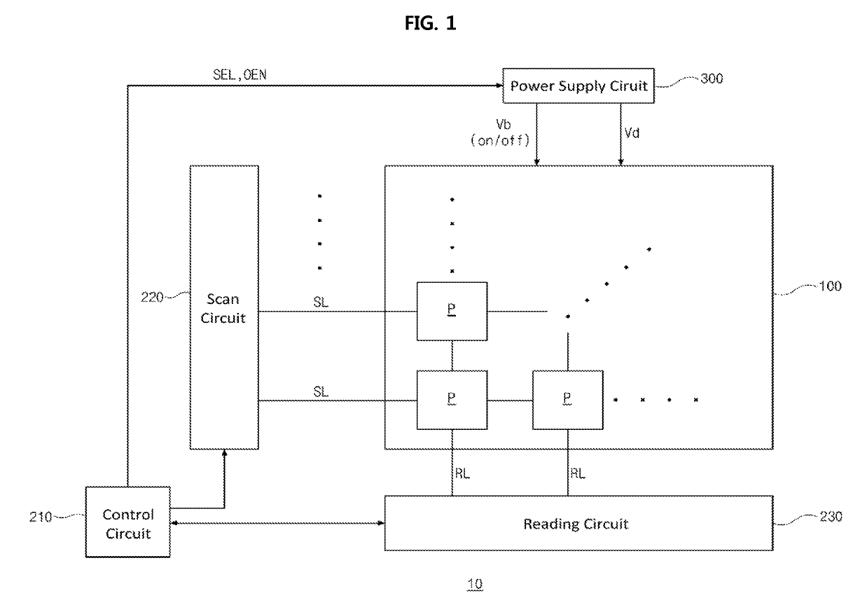

FIG. 1 is a schematic diagram illustrating an X-ray detector according to one embodiment of the present invention.

Referring to FIG. 1, according to one embodiment of the present invention, an X-ray detector 10 includes a sensor panel 100, a driving circuit that drives the sensor panel 100, and a power supply circuit 300 that supplies a driving voltage to the X-ray detector 10.

As the sensor panel 100, a direct conversion sensor panel 100 that directly converts incident X-rays into an electrical signal is used.

The sensor panel 100 includes a plurality of scan lines SL formed to extend in a row direction on a substrate and a plurality of reading lines RL formed to extend in a column direction on the substrate. In addition, the sensor panel 100 further includes a plurality of pixels P, each serving as a unit photo-electric conversion element, arranged in matrix, along row lines and column lines. The pixels P are connected to the scan lines and the reading lines.

Each pixel P includes a switch element connected to the scan line SL and the reading line RL and a photoelectric conversion element electrically connected to the switch element.

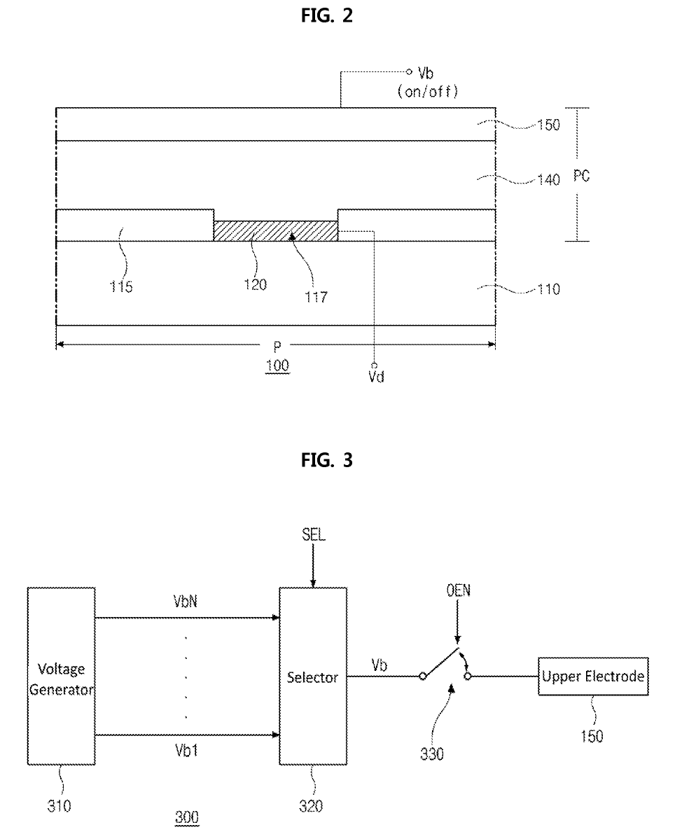

The pixel P provided with the photoelectric conversion element is described in greater detail with reference to FIG. 2.

FIG. 2 is a cross-sectional view illustrating the construction of the pixel of the X-ray detector according to one embodiment of the present invention. For ease of description, FIG. 2 illustrates only a photoelectric conversion element PC of a pixel PC.

Referring to FIG. 2, one pixel P includes one photoelectric conversion element PC that coverts X-rays into an electrical signal, and the photoelectric conversion element PC is formed on a substrate 110.

Examples of the substrate 110 used for the sensor panel 100 include a CMOS substrate, a glass substrate, a graphite substrate, and an aluminum-ITO substrate in which an ITO layer is stacked on an aluminum oxide (Al₂O₃) base. However, the substrate 110 is not limited to these examples. For ease of description, the present embodiment uses a CMOS substrate as the substrate 110.

A protective film 115 is formed on the surface of the substrate 110. The protective film 115 is made from an inorganic insulating material, for example, silicon dioxide (SiO₂) or silicon nitride (SiNₓ). However, the material of the protective film 115 is not limited thereto.

The protective film 115 is provided with pad holes 117 for each pixel P. A lower electrode 120 is provided in the pad hole 117. The lower electrode 120 is one electrode of two electrodes constituting the photoelectric conversion element PC and corresponds to a first electrode 120.

The lower electrode 120 is made from a material that can form a Schotty junction with a photoconductive layer 140. For example, the lower electrode 120 can be made from aluminum (Al). However, the material of the lower electrode 120 is not limited thereto.

In the present embodiment, electrons with higher mobility than holes are collected by the lower electrode 120. In this case, at the time of X-ray irradiation, a driving voltage Vd applied to the lower electrode 120 is higher than a bias voltage Vb applied to the upper electrode 150. That is, the driving voltage Vd is a positive voltage with respect to the bias voltage Vb.

The substrate 110 on which the lower electrode 120 is formed is further provided with the photoconductive layer 140. The photoconductive layer 140 irradiated with X-rays generates electron-hole pairs. The photoconductive layer 140 is made from a material having high electric charge mobility, high absorptivity coefficient, low dark current, and low electron-hole-pair generation energy. For example, the photoconductive layer 140 is made from a photoconductive material selected from the group consisting of CdTe, CdZnTe, PbO, PbI₂, HgI₂, GaAs, Se, TlBr, and BiI₃.

The substrate 110 on which the photoconductive layer 140 is formed is further provided with the upper electrode 150. The upper electrode 150 is the other electrode of the two electrodes constituting the photoelectric conversion element PC. The upper electrode 150 corresponds to a second electrode 150 herein. The upper electrode 150 is formed to cover the entire area of an active region of the sensor panel 100. The active area is provided with the pixels P.

The upper electrode 150 is made from a material that can form an ohmic contact with the photoconductive layer 140. For example, the upper electrode 150 is made from gold (Au) or platinum (Pt), or alloys of these, but the material of the upper electrode 150 is not limited to these examples.

In the present embodiment, the upper electrode 150 may be applied with a bias voltage Vb serving as a driving voltage, or may not be applied with any voltage. That is, the sensor panel 100 can be driven by applying a driving voltage (bias voltage) to the upper electrode 150 or by leaving the upper electrode floating.

In a case where the bias voltage Vb is applied to the upper electrode, a voltage level selected from a plurality of voltage levels can be applied as the bias voltage. The level of the bias voltage Vb applied to the upper electrode can be controlled.

That is, it is possible to reduce power consumption by switching driving mode between bias voltage application mode in which a bias voltage is applied to the upper electrode 150 and floating mode in which the upper electrode 150 is in a floating state, or by adjusting the level of the bias voltage applied to the upper electrode 150 in the case of the voltage application mode.

With regard this, in accordance with the purposes of X-rays radiography such as medical diagnosis, a high resolution X-ray image may be necessary required or a low resolution X-ray image may be satisfactory. That is, the required resolution of X-ray images varies according to the purposes of X-ray radiography.

When high resolution X-ray images are required, a relatively high-level bias voltage is applied to the upper electrode 150 so that the lower electrode 120 can collect a relatively large amount of electric charges.

Conversely, when relatively low resolution X-ray images are satisfactory, a relatively low-level bias voltage is applied to the upper electrode 150 or no voltage is applied to the upper electrode 150 such that the upper electrode 150 is electrically floating. In this case, the lower electrode 120 collects a relatively small amount of electric charges.

In short, according to the embodiment of the present invention, the level of the bias voltage applied to the upper electrode 150 is adaptively adjusted or no voltage is applied to the upper electrode 150, in accordance with the required image resolution. Therefore, it is possible to reduce overall power consumption compared with a conventional driving method by which a high-level bias voltage is continuously applied to the upper electrode regardless of required image resolutions.

Referring again to FIG. 1, the driving circuit that drives the sensor panel 100 described above includes a control circuit 210, a scan circuit 220, and a reading circuit 230.

The control circuit 210 receives a control signal transmitted from an external system, and outputs a control signal to drive the scan circuit 220 and the reading circuit 230. In addition, the control circuit 210 receives an image signal that is an electrical signal transmitted from the reading circuit 230 and then transmits the image signal to the external system.

The control circuit 210 also outputs a control signal, referred to as an output control signal, to enable or disable an output signal, i.e. the bias voltage, of the power supply circuit 300 in accordance with required X-ray image resolutions. For example, the control circuit 210 outputs the output control signal including a selection signal SEL and an output enable signal OEN to enable or disable the output signal (i.e. the bias voltage) of the power supply circuit 300.

Operation of the power supply circuit 300 controlled by the output control signal of the control circuit 210 is described below in detail.

The scan circuit 220 is driven by the control signal transmitted from the control circuit 210. The scan circuit 220 sequentially scans the scan lines SL and applies an ON-level scan signal. Therefore, each row line is sequentially selected, and data items, i.e. image signals, stored in the pixels P connected to the selected row line are output to the corresponding reading line RL.

The reading circuit 230 is driven by the control signal transmitted from the control circuit 210. The reading circuit 230 receives the image signals that have been stored in the pixels P through the reading line RL for each row line. That is, the reading circuit 230 reads the image signals row line by row line. The data items are then transmitted to the control circuit 210.

The power supply circuit 300 serves as a driving voltage source for supplying driving voltages to components constituting the X-ray detector 10.

Specifically, the power supply circuit 300 operates to adjust the level of the bias voltage Vb applied to the upper electrode 150 or to control an output of the bias voltage Vb to the upper electrode 150 to be on/off in accordance with the output control signal transmitted from the control circuit 210, whereby it reduces power consumption.

Details of the power supply circuit 300 will be described with reference to FIG. 3. Referring to FIG. 3, the power supply circuit 300 includes a voltage generator 310, a selector 320, and a switch 330.

The voltage generator 310 generates two or more bias voltages Vb1 to VbN having different levels (first level to N-th level). The first-level bias voltage Vb1 corresponds to the lowest-level bias voltage and the N-th-level bias voltage VbN corresponds to the highest-level bias voltage. The magnitude of voltage is an absolute value.

The bias voltages Vb1 to BvN generated by the voltage generator 310 are output to the selector 320. The selector 320 selects any one-level bias voltage from the bias voltages Vb1 to VbN and outputs the selected bias voltage in accordance with the selection signal SE transmitted from the control circuit 210. The selector 320 is, for example, a multiplexer, but it is not limited to the multiplexer.

With regard to the bias voltage output performed by the selector 320, when a relatively high resolution X-ray image is required, the selector 320 selects and outputs a relatively high-level bias voltage. Meanwhile, when a relatively low resolution X-ray image is required, the selector 320 selects and outputs a relatively low-level bias voltage.

The switch 330 is turned on or off in accordance with the output enable signal OEN transmitted from the control circuit 210 so that the bias voltage Vb can be output or cannot be output from the power supply circuit 300. For example, the switch 330 is connected to a back stage, i.e. an output terminal, of the selector 320, thereby enabling or disabling the bias voltage Vb selected and output by the selector 320.

That is, when switch 330 is turned on, the bias voltage Vb, output from the selector 320, passes through the switch 33 and enters into the sensor panel 100, and accordingly the upper electrode 150 is applied with the selected bias voltage Vb. That is, the upper electrode 150 becomes a voltage-applied state.

Conversely, when the switch 330 is turned off, the bias voltage Vb, output from the selector 320, cannot pass through the switch 330 and thus cannot enter into the sensor panel 100. Therefore, the upper electrode 150 enters a floating state in which the bias voltage is not applied to the upper electrode.

In this way, whether the upper electrode 150 is applied with the bias voltage or not is determined by the on/off control of the switch 330.

That is, when the switch 330 is turned off, since the upper electrode 150 is not applied with any voltage, power consumption can be minimized.

The X-ray detector 10 described above can be applied to a front side irradiation system or a back side irradiation system.

In the front side irradiation system, X-rays are irradiated in a direction from the upper electrode 150 to the substrate 110. Meanwhile, in the back side irradiation system, X-rays are irradiated in a direction from the back surface of the substrate 110 to the upper electrode 150.

The substrate 110 is provided with various driving elements such as transistors. Therefore, in the case of the back side irradiation system, the X-ray sensitivity is likely to be deteriorated, resulting in degradation in image quality.

However, as described above, according to the embodiment of the present invention, the bias voltage Vb can be controlled in accordance with required image quality. Therefore, when X-ray radiography is performed with the back side irradiation system, it is possible to compensate for the deterioration in the X-ray sensitivity by applying a relatively high-level bias voltage Vb.

Therefore, the X-ray detector according to the embodiment of the present invention can be effectively used in a back side irradiation system as well as a front side irradiation system.

As described above, according to the embodiment of the present invention, in accordance with the required image resolution, the voltage level of the bias voltage applied to the upper electrode can be adjusted. In addition, electrical connection between the upper electrode and the power supply circuit can be cut off whereby the upper electrode becomes floating. Therefore, power consumption is considerably reduced as compared with conventional technologies in which a high-level bias voltage is continuously applied to the upper electrode regardless of the required image resolution.

Furthermore, the X-ray detector can be applied to back side irradiation systems as well as front side irradiation systems.

1. An X-ray detector comprising:
a first electrode formed on a substrate;
a photoconductive layer formed on the first electrode;
a second electrode formed on the photoconductive layer and configured to be in a voltage applied state with a bias voltage or a floating state;
a power supply circuit configured to control an output of the bias voltage to be on/off; and
wherein the power supply circuit selects any bias voltage ranging from a first-level bias voltage to an N-th-level bias voltage, and controls an output of the selected bias voltage to be on/off, wherein the N is 2 or greater.

2. The X-ray detector according to claim 1, wherein the selected bias voltage is selected in accordance with a required image quality.

3. The X-ray detector according to claim 2, wherein the power supply circuit includes a voltage generator configured to generate from the first-level bias voltage to the N-th-level bias voltage and a selector configured to select any bias voltage ranging from the first-level bias voltage to the N-th-level bias voltage generated by the voltage generator.

4. The X-ray detector according to claim 1, wherein the power supply circuit is configured to control the output of the bias voltage such that the second electrode to be in a voltage applied state or a floating state.

5. The X-ray detector according to claim 1, wherein the photoconductive layer is made from at least one material selected from a group consisting of CdTe, CdZnTe, PbO, PbI₂, HgI₂, GaAs, Se, TlBr, and BiI₃.

6. The X-ray detector according to claim 1, wherein X-rays are incident onto the second electrode or to a back surface of the substrate.

7. The X-ray detector according to claim 1, wherein the second electrode is made from gold (Au), platinum (Pt), or an alloy of these.

8. (canceled)

9. (canceled)
